(19) United States
(12) Patent Application Publication
(10) Pub. No.: US 2006/0192621 A1
(43) Pub. Date: Aug. 31, 2006

(54) Two-system PLL frequency synthesizer

(76) Inventors: Tomoaki Maeda, Kyoto (JP); Atsushi Ohara, Shiga (JP); Koichi Mizuno, Nara (JP)

Correspondence Address: WENDEROTH, LIND & PONACK L.L.P., 2033 K. STREET, NW, SUITE 800, WASHINGTON, DC, 20006, US

(21) Appl. No.: 11/360,817

(22) Filed: Feb. 24, 2006

(30) Foreign Application Priority Data
Feb. 28, 2005 (JP) 2005-054667

(51) Int. Cl. H03L 7/00

(52) U.S. Cl. 331/2

(57) ABSTRACT

A two-system PLL frequency synthesizer includes, a first PLL frequency synthesizer connected with a power line, a current amount controller having a first constant current source connected between the first PLL frequency synthesizer and a ground line, and a constant current source controller for controlling the current of the first constant current source so as to change it gradually, and a series-connected circuit of a second PLL frequency synthesizer and a second constant current source, connected between the power line and the ground line.

### BACKGROUND OF THE INVENTION

The present invention relates to a two-system PLL (Phase Locked Loop) frequency synthesizer, and in more detail, relates to a two-system PLL (Phase Locked Loop) frequency synthesizer capable of determining operation or non-operation of at least one-system PLL frequency synthesizer based on a control signal from the outside. In recent years, a duplex system in which transmission and reception are performed simultaneously is widely used in wireless communication devices such as mobile telephones and PHS (Personal Handy phone System). Further, as a means for generating local oscillation signals of a wireless communication device, a PLL frequency synthesizer is generally used. In the duplex system, there is required a two-system PLL frequency synthesizer including a first PLL frequency synthesizer for generating local oscillation signals for transmission and a second PLL frequency synthesizer for generating local oscillation signals for reception which must be operated simultaneously.

A conventional two-system PLL frequency synthesizer, as described in the publication of Japanese Unexamined Patent Publication No. 2002-330069 (FIG. 11), will be explained by using FIGS. 8 and 9.

FIG. 8 is a block diagram of a conventional two-system PLL frequency synthesizer. As shown in FIG. 8, a series-connected circuit including a first PLL frequency synthesizer 83a, a switch 85 and a constant current source 84a, and a series-connected circuit having a second PLL frequency synthesizer 83b and a constant current source 84b are connected in parallel between a power line (VDD) 81 and a ground line (GND) 82. The first PLL frequency synthesizer 83a and the second PLL frequency synthesizer 83b have configurations well-known in this technical field. In general, a PLL frequency synthesizer including an analog circuit block and a digital circuit block, and a bias current is required to operate the analog circuit block. The constant current source 84a generates a bias current I required for operating the first PLL frequency synthesizer 83a. The constant current source 84b generates a bias current required for operating the second PLL frequency synthesizer 83b. In the switch 85, its on/off operation is controlled with an operation or non-operation (hereinafter referred to as operation/non-operation) switching signal inputted via an operation/non-operation switching signal input terminal 86.

FIG. 9 is a waveform diagram of an operation/non-operation switching signal of a conventional two-system PLL frequency synthesizer configured as described above and a current flowing through the first PLL frequency synthesizer 83a. As shown in FIG. 9, when the operation/non-operation switching signal is changed from High to Low, the bias current I flows through the first PLL frequency synthesizer 83a instantaneously, so that the first PLL frequency synthesizer 83a starts operation at once. On the other hand, when the operation/non-operation switching signal is changed from Low to High, the bias current I1 flowing through the first PLL frequency synthesizer 3a becomes 0A instantaneously, so that the first PLL frequency synthesizer 3a stops operation at once to thereby be in a non-operated state.

The conventional two-system PLL frequency synthesizer has been adapted to control the on/off operation of the switch 85 with the operation/non-operation switching signal to thereby control operation/non-operation of the first PLL frequency synthesizer 83a so as to reduce power consumption.

However, in the conventional two-system PLL frequency synthesizer, in order to switch operation/non-operation of the first PLL frequency synthesizer 83a, the bias current I is changed instantaneously. As the bias current I changes rapidly, impedances of the power line 81 and the ground line 82 change rapidly as well. Since the power line 1 and the ground line 2 are commonly used in the two systems of the first PLL frequency synthesizer 83a and the second PLL frequency synthesizer 83b, the second PLL frequency synthesizer 83b which is lock-operating via the power line 81 and the ground line 82 is interfered. Thereby, in the conventional two-system PLL frequency synthesizer, there has been a problem that the lock frequency of the lock-operating second PLL frequency synthesizer 83b fluctuates.

It is therefore an object of the present invention to provide a two-system PLL frequency synthesizer capable of preventing fluctuations of lock frequency of a lock-operating one-system PLL frequency synthesizer, caused corresponding to switching of operation/non-operation of the other one-system PLL frequency synthesizer.

### SUMMARY OF THE INVENTION

In order to achieve the above-mentioned object, according to a first aspect of the present invention, there is provided a two-system PLL frequency synthesizer comprising:

a first PLL frequency synthesizer connected with a power line;

a current amount controller including a first constant current source connected between the first PLL frequency synthesizer and a ground line, and a constant current source controller for controlling current of the first constant current source so as to change gradually; and

a series-connected circuit of a second PLL frequency synthesizer and a second constant current source, connected between the power line and the ground line.

According to the first aspect, the current amount of a bias current for operating a one-system PLL frequency synthesizer by the current amount controller is controlled to change not instantaneously but gradually. Thereby, it is possible to prevent fluctuations of lock frequency of a lock-operating one-system PLL frequency synthesizer, caused due to switching of operation/non-operation of the other one-system PLL frequency synthesizer.

According to a second aspect of the present invention, there is provided the two-system PLL frequency synthesizer as defined in the first aspect, wherein the constant current source controller changes the current of the first constant current source continuously with respect to time.

According to a third aspect of the present invention, there is provided the two-system PLL frequency synthesizer as defined in the first aspect, wherein the constant current source controller changes the current of the first constant current source stepwise.

According to a fourth aspect of the present invention, there is provided the two-system PLL frequency synthesizer as defined in the first aspect, wherein the current amount controller includes, instead of the first constant current source and the constant current source controller:

a current mirror circuit connected in series with the first PLL frequency synthesizer;

a switching transistor, connected with the current mirror circuit, for controlling current of the current mirror circuit; and

a capacitor connected in parallel with the switching transistor.

According to a fifth aspect of the present invention, there is provided the two-system PLL frequency synthesizer as defined in the fourth aspect, wherein the current mirror circuit includes:

a first current mirror transistor connected in series with the first PLL frequency synthesizer; and

a series-connected circuit of a third constant current source and a second current mirror transistor, connected in parallel with a series-connected circuit of the first PLL frequency synthesizer and the first current mirror transistor, and
a gate of the second current mirror transistor is connected with a gate of the first current mirror transistor, and a connecting point of the third constant current source and the second current mirror transistor.

According to a sixth aspect of the present invention, there is provided the two-system PLL frequency synthesizer as defined in the first aspect, wherein the current amount controller includes, instead of the first constant current source and the constant current source controller:

a parallel-connected circuit, connected in series with the first PLL frequency synthesizer, in which a plurality of series-connected circuits of switching devices and constant current sources are connected in parallel; and

a counter for controlling on/off of the switching devices.

According to a seventh aspect of the present invention, there is provided the two-system PLL frequency synthesizer as defined in the first aspect, wherein the current amount controller includes, instead of the first constant current source and the constant current source controller:

a parallel-connected circuit, connected in series with the first PLL frequency synthesizer, in which a plurality of series-connected circuits of switching devices and first current mirror transistors are connected in parallel;

a counter for controlling on/off of the switching devices;

a series-connected circuit of a third constant current source and a second current mirror transistor, connected in parallel with the first PLL frequency synthesizer and the series-connected circuits of the switching devices and the first current mirror transistors, and
a gate of the second current mirror transistor is connected with gates of the first current mirror transistors, and a connecting point of the third constant current source and the second current mirror transistor.

According to an eighth aspect of the present invention, there is provided the two-system PLL frequency synthesizer as defined in the first aspect, wherein the current amount controller includes, instead of the first constant current source and the constant current source controller:

a first current mirror transistor connected in series with the first PLL frequency synthesizer;

a series-connected circuit of a parallel-connected circuit in which a plurality of series-connected circuits of constant current sources and switching devices are connected in parallel and a second current mirror transistor, connected in parallel with a series-connected circuit of the first PLL frequency synthesizer and the first current mirror transistor; and

a counter for controlling on/off of the switching devices, and

a gate of the second current mirror transistor is connected with a gate of the first current mirror transistor, and a connecting point of the switching devices and the second current mirror transistor.

According to each aspect of the present invention, the current amount of a bias current for operating a one-system PLL frequency synthesizer by the current amount controller is controlled to change not instantaneously but gradually. Thereby, in a two-system PLL frequency synthesizer, it is possible to prevent fluctuations of a lock frequency of a lock-operating one-system PLL frequency synthesizer, caused due to switching of operation/non-operation of the other one-system PLL frequency synthesizer.

### BRIEF DESCRIPTION OF THE DRAWINGS

These and other objects of the present invention will be apparent from the following description relating to preferred embodiments for the accompanying drawings, in which

FIG. 1 is a block diagram of a two-system PLL frequency synthesizer according to a first embodiment of the present invention;

FIG. 2 is a circuit diagram of a two-system PLL frequency synthesizer according to a second embodiment of the present invention;

FIG. 3 is a waveform diagram of each part of the two-system PLL frequency synthesizer according to the second embodiment of the present invention;

FIG. 4 is a circuit diagram of a two-system PLL frequency synthesizer according to a third embodiment of the present invention;

FIG. 5 is a waveform diagram of each part of the two-system PLL frequency synthesizer according to the third embodiment of the present invention;

FIG. 6 is a circuit diagram of a two-system PLL frequency synthesizer according to a fourth embodiment of the present invention;

FIG. 7 is a circuit diagram of a two-system PLL frequency synthesizer according to a fifth embodiment of the present invention;

FIG. 8 is a block diagram of a conventional two-system PLL frequency synthesizer; and

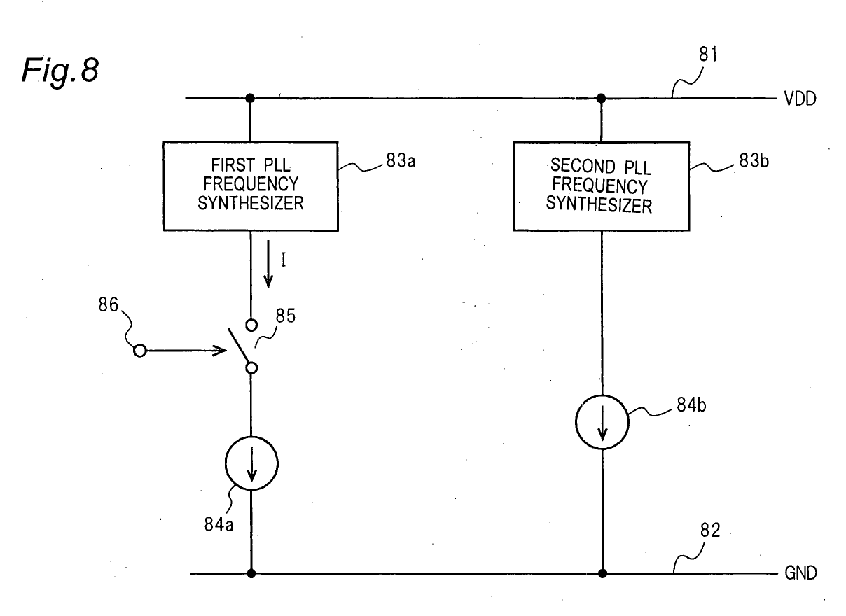

FIG. 9 is a waveform diagram of each part of the conventional two-system PLL frequency synthesizer.

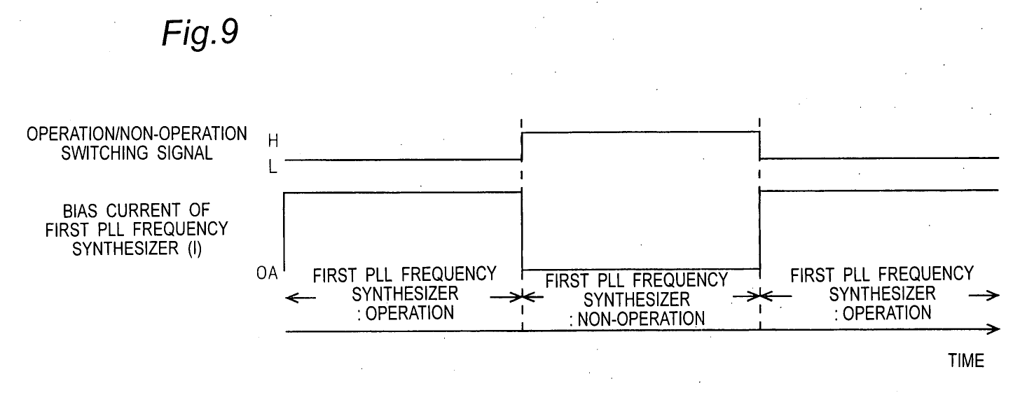

### DETAILED DESCRIPTION OF THE PREFERRED EMBODIMENTS

Before continuing the description of the present invention, note that the same components are denoted by the same reference numerals in the accompanying drawings.

Hereinafter, a two-system PLL frequency synthesizer according to preferred embodiments of the present invention will be explained with reference to the drawings.

### FIRST EMBODIMENT

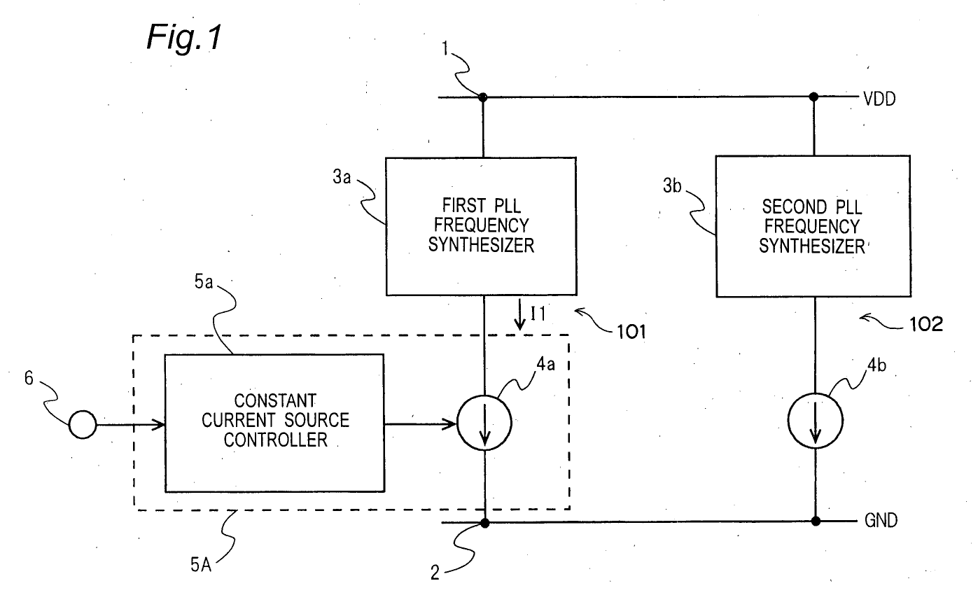

A two-system PLL frequency synthesizer according to a first embodiment of the present invention will be explained by using FIG. 1. FIG. 1 is a block diagram showing the two-system PLL frequency synthesizer of the first embodiment. In FIG. 1, the two-system PLL frequency synthesizer of the first embodiment includes: a first PLL frequency synthesizer 3a; a second PLL frequency synthesizer 3b; a current amount controller 5A having a constant current source 4a and a constant current source controller 5a ; a constant current source 4b; and an operation/non-operation switching signal input terminal 6. As shown in FIG. 1, a series-connected circuit 101 having the first PLL frequency synthesizer 3a and the constant current source 4a and a series-connected circuit 102 having the second PLL frequency synthesizer 3b and the constant current source 4b are connected in parallel between a power line (VDD) 1 and a ground line (GND) 2. The first PLL frequency synthesizer 3a and the second PLL frequency synthesizer 3b have configurations well-known in this technical field. The constant current source 4a generates a bias current I1 required for operating the first PLL frequency synthesizer 3a . The constant current source 4b generates a bias current required for operating the second PLL frequency synthesizer 3b. The constant current source controller 5a controls the current value of the bias current I1 of the constant current source 4a so as to change gradually (e.g., continuously or stepwise with respect to time) corresponding to an operation/non-operation switching signal inputted from the outside via the operation/non-operation switching signal input terminal 6.

The two-system PLL frequency synthesizer of the first embodiment is configured as described above.

According to the two-system PLL frequency synthesizer of the first embodiment, the bias current I1 for operating or not operating the first PLL frequency synthesizer 3a is controlled not to change rapidly but to change gradually by the current amount controller 5A. Thereby, it is possible to prevent fluctuations of the lock frequency of the second PLL frequency synthesizer 3b in a locking operation.

### SECOND EMBODIMENT

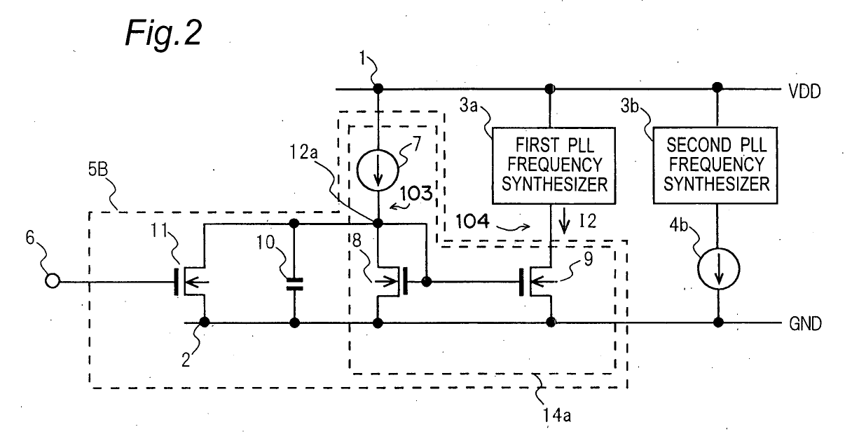

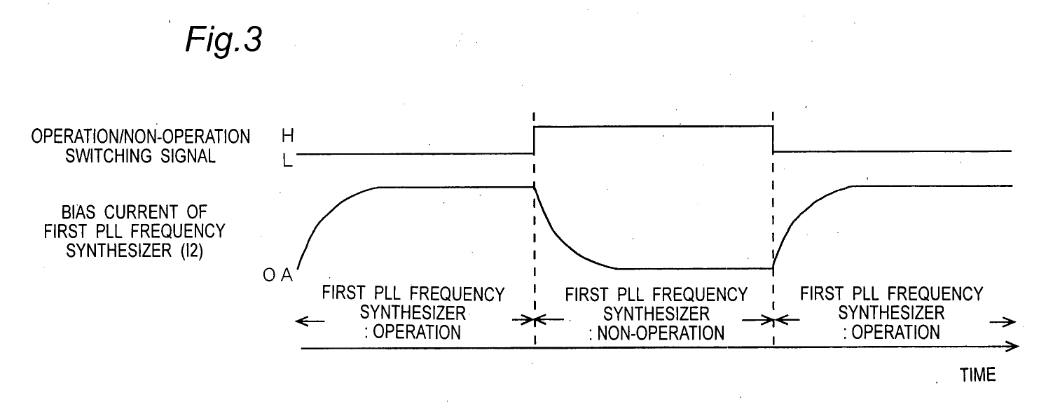

A two-system PLL frequency synthesizer according to a second embodiment of the present invention will be explained by using FIGS. 2 and 3. The two-system PLL frequency synthesizer of the second embodiment is different from the two-system PLL frequency synthesizer of the first embodiment in such an aspect that a current amount controller 5B is provided instead of the current amount controller 5A. Other aspects are the same, so overlapping explanation is omitted.

FIG. 2 is a circuit diagram of the two-system PLL frequency synthesizer of the second embodiment. In FIG. 2, the current amount controller 5B includes: a current mirror circuit 14a having a constant current source 7 and current mirror transistors 8 and 9; a capacitor 10; and a switching transistor 11.

The constant current source 7 is connected in series with the current mirror transistor 8. The current mirror transistor 9 is connected in series with the first PLL frequency synthesizer 3a. The current mirror transistors 8 and 9 are MOS field effect transistors (MOSFETs). The gate of the current mirror transistor 8 is connected with the gate of the current mirror transistor 9 and a connecting point 12a of the constant current source 7 and tne current mirror transistor 8. A series-connected circuit 103 of the constant current source 7 and the current mirror transistor 8 and a series-connected circuit 104 of the first PLL frequency synthesizer 3a and the current mirror transistor 9 are connected in parallel between the power line 1 and the ground line 2.

The current mirror circuit 14a including the constant current source 7 and the current mirror transistors 8 and 9 generates a bias current I2 for operating the first PLL frequency synthesizer 3a. The current value of the bias current I2 becomes one that the current value of the constant current source 7 is mirrored (copied) corresponding to the size ratio between the current mirror transistor 8 and the current mirror transistor 9.

The capacitor 10 and the switching transistor 11 are connected with the current mirror transistor 8 in parallel, respectively. The switching transistor 11 is an Nch-type MOSFET. The switching transistor 11 is turned off when an operation/non-operation switching signal inputted into the gate thereof via the operation/non-operation switching signal input terminal 6 is Low, and is turned on when it is High.

Next, operation of the two-system PLL frequency synthesizer of the second embodiment configured as described above will be explained. First, an operation/non-operation switching signal is inputted into the gate of the switching transistor 11 via the operation/non-operation switching signal input terminal 6. When the operation/non-operation switching signal changes from High to Low, the switching transistor 11 is changed from on to off. Thereby, the capacitor 10 is charged by the constant current source 7. Here, assuming that parallel inside impedance of the constant current source 7 is Rc and capacitance of the capacitor 10 is C0, the time constant τc at the time of charging of the capacitor 10 is shown by the following equation (1):
τc=Rc·C0 (1)
Accordingly, the gate voltage of the current mirror transistor 9 rises continuously with respect to time from 0 V. with a time constant determined by the equation (1). Therefore, the bias current I2 of the first PLL frequency synthesizer 3a also increases continuously with respect to time.

On the other hand, when the operation/non-operation switching signal changes from Low to High, the switching transistor 11 changes from off to on. Thereby, the charges accumulated on the capacitor 10 are discharged. Here, assuming that ON resistance of the switching transistor 11 is Rd, the time constant τd at the time of discharging of the capacitor 10 is shown by the following equation (2):
τd=Rd·C0 (2)

Accordingly, the gate voltage of the current mirror transistor 9 drops continuously with respect to time with a time constant determined by the equation (2). Therefore, the bias current I2 of the first PLL frequency synthesizer 3a also decreases continuously with respect to time.

FIG. 3 shows waveforms of an operation/non-operation switching signal of the two-system PLL frequency synthesizer of the second embodiment and the bias current I2 for operating the first PLL frequency synthesizer 3a .

As shown in FIG. 3, when the operation/non-operation switching signal changes from High to Low, the bias current I2 increases continuously with respect to time. Accordingly, the first PLL frequency synthesizer 3a starts operation with a delay with respect to time. Further, when the operation/non-operation switching signal changes from Low to High, the bias current I2 decreases continuously with respect to time. Accordingly, the first PLL frequency synthesizer 3b stops operation with a delay with respect to time.

According to the two-system PLL frequency synthesizer of the second embodiment, rapid changes of the bias current I1 can be prevented by utilizing a fact that the charges of the capacitor 10 are charged or discharged with a predetermined time constant. Accordingly, fluctuations of the lock frequency of the second PLL frequency synthesizer 3b in a locking operation can be prevented.

### THIRD EMBODIMENT

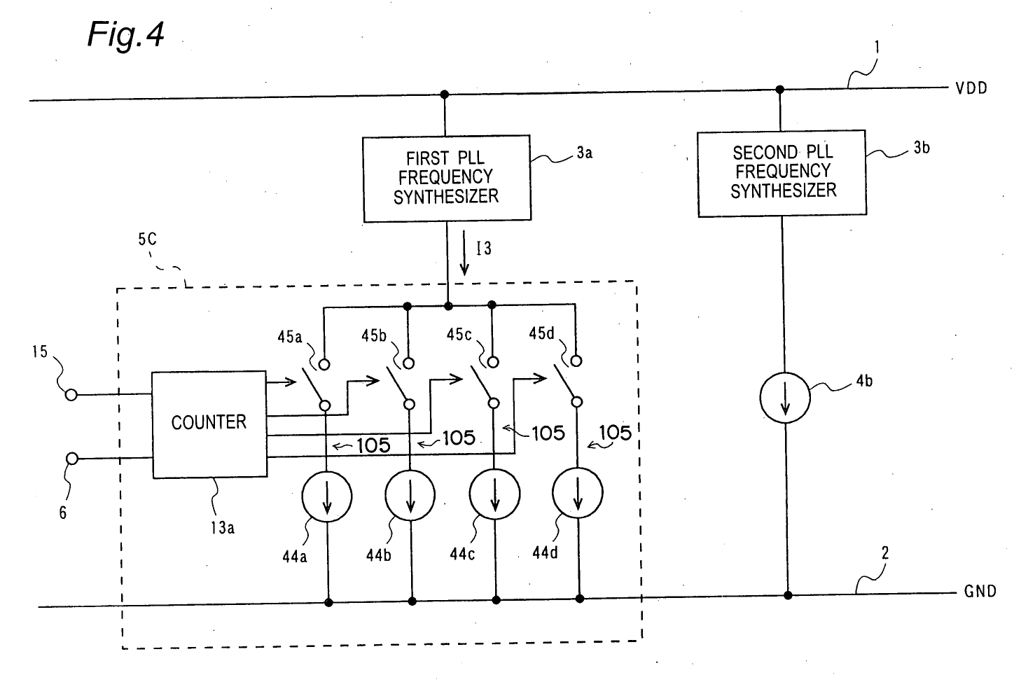

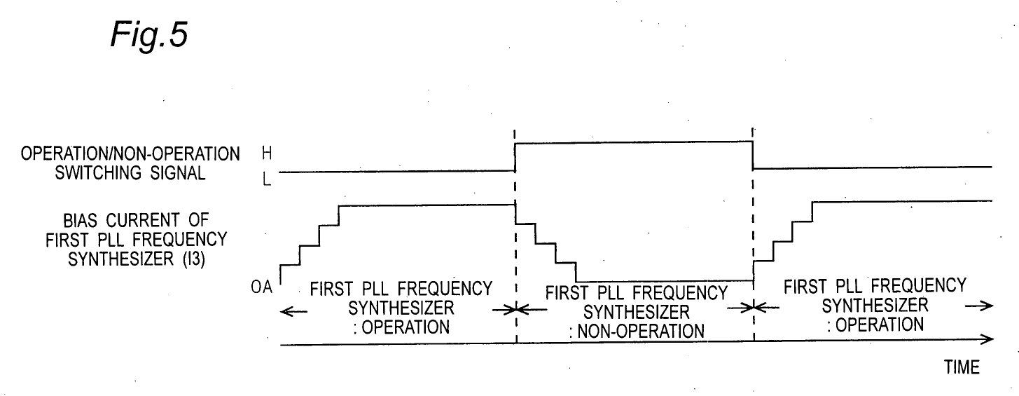

A two-system PLL frequency synthesizer according to a third embodiment of the present invention will be explained by using FIGS. 4 and 5. The two-system PLL frequency synthesizer of the third embodiment is different from the two-system PLL frequency synthesizer of the first embodiment in such aspects that a current amount controller 5C is provided instead of the current amount controller 5A and a clock input terminal 15 is further included. Other aspects are the same, so overlapping description is omitted.

FIG. 4 shows a circuit diagram of the two-system PLL frequency synthesizer of the third embodiment. In FIG. 4, the current amount controller 5C includes constant current sources 44a to 44d, switches 45a to 45d and a counter 13a.

Each of the constant current sources 44a to 44d generates an equal predetermined current. The switches 45a to 45d are switching devices such as switching circuits using semiconductors. The constant current source 44a and the switch 45a are connected in series. Similarly, the constant current sources 44b to 44d and the switches 45b to 45d are connected in series, respectively. The respective series—connected circuits 105 having the respective constant current sources (44a to 44d) and the respective switches (45a to 45d ) are connected in parallel between the first PLL frequency synthesizer 3a and the ground line 2. The current value of the bias current I3 for operating the first PLL frequency synthesizer 3a becomes the sum of the current values of the predetermined currents flowing via switches (45a to 45d ) in the ON state.

The counter 13a controls on/off operation of the switches 45a to 45d corresponding to operation/non-operation switching signals inputted via the operation/non-operation switching signal input terminal 6 and clock signals inputted via the clock input terminal 15.

Next, operation of the two-system PLL frequency synthesizer of the third embodiment will be explained. First, an operation/non-operation switching signal is inputted into the counter 13a via the operation/non-operation switching signal input terminal 6. When the operation/non-operation switching signal is Low, the counter 13a counts up clock signals inputted via the clock input terminal 15, and turns on the switches 45a to 45d one by one sequentially. When the operation/non-operation switching signal is High, the counter 13a counts down clock signals and turns off the switches 45a to 45d one by one sequentially.

FIG. 5 shows waveforms of an operation/non-operation switching signal of the two-system PLL frequency synthesizer of FIG. 4 and the bias current I3 for operating the first PLL frequency synthesizer 3a . When the operation/non-operation switching signal changes from High to Low, the counter 13a turns on the switches 45a to 45d one by one sequentially so as to increase the bias current I3 stepwise. Thereby, the first PLL frequency synthesizer 3a starts operation with a delay with respect to time. When the operation/non-operation switching signal changes from Low to High, the counter 13a turns off the switches 45a to 45d one by one sequentially so as to decrease the bias current I3 stepwise. Thereby, the first PLL frequency synthesizer 3a stops operation with a delay with respect to time.

According to the two-system PLL frequency synthesizer of the third embodiment, by tuning on or off the switches 45a to 45d one by one sequentially, it is possible to change the bias current I3 stepwise to thereby prevent rapid changes of the bias current I3. Accordingly, it is possible to prevent fluctuations of lock frequency of the second PLL frequency synthesizer 3b in a locking operation.

Note that although the two-system PLL frequency synthesizer of the third embodiment is configured to include four series-connected circuits 105 having the constant current sources. (44a to 44d) and the switches (45a to 45d ), the same effect can be obtained with a configuration having at least two series-connected circuits 105.

Further, although the current values of the current generated by the constant current sources 44a to 44d are equal in the two-system PLL frequency synthesizer of tne third embodiment, the current values of the current generated by the constant current sources 44a to 44d may be weighted, respectively. That is, although the current values of the constant current sources 44a to 44d are set to (1:1:1:1), the same effect can be achieved with (1:2:4:8), for example.

### FOURTH EMBODIMENT

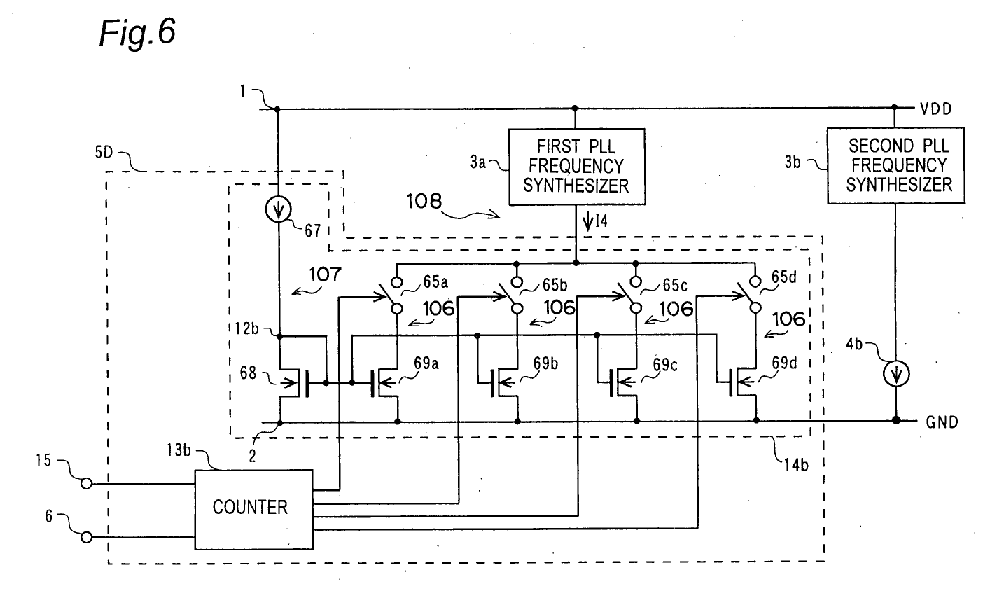

A two-system PLL frequency synthesizer according to a fourth embodiment of the present invention will be explained by using FIG. 6. The two-system PLL frequency synthesizer of the fourth embodiment is different from the two-system PLL frequency synthesizer of the third embodiment in such an aspect that a current amount controller 5D is provided instead of the current amount controller 5C. Other aspects are the same, so overlapping description is omitted.

FIG. 6 is a circuit diagram of the two-system PLL frequency synthesizer of the fourth embodiment. In FIG. 6, the current amount controller 5D includes: a constant current source 67; a current mirror circuit 14b having current mirror transistors 68 and 69a to 69d and switches 65a to 65d; and a counter 13b.

The current mirror transistors 68 and 69a to 69d are MOSFETs, respectively. The switches 65a to 65d are one example of switching devices such as switching circuits using semiconductors. The current mirror transistor 69a and the switch 65a are connected in series. Similarly, the current mirror transistors 69b to 69d and the switches 65b to 65d are connected in series, respectively. The respective series-connected circuits 106 having the respective current mirror transistors (69a to 69d) and the respective switches (65a to 65d) are connected in parallel between the first PLL frequency synthesizer 3a and the ground line 2, respectively.

The constant current source 67 generates a predetermined current. A series-connected circuit 107of the constant current source 67 and the current mirror transistor 68 is connected in parallel with a series-connected circuit 108 of the first PLL frequency synthesizer 3a and a parallel-connected circuit (65a to 65d, 69a to 69d).having the respective series-connected circuits 106. The gate of the current mirror transistor 68 is connected with each of the gates of the current mirror transistors 69a to 69d and a connecting point 12b of the constant current source 67 and the current mirror transistor 68.

The current mirror circuit 14b including the constant current source 67, the current mirror transistors 68 and 69a to 69d and the switches 65a to 65d generates a bias current I4 for operating the first PLL frequency synthesizer 3a. The current value of the bias current I4 becomes the sum of values that the current value of the constant current source 67 is mirrored (copied) corresponding to size ratios between the current mirror transistor 68 and the current mirror transistors 69a to 69d, respectively.

The counter 13b controls on/off operation of the switches 65a to 65d corresponding to operation/non-operation switching signals inputted via the operation/non-operation switching signal input terminal 6 and clock signals inputted via the clock input terminal 15.

The operation and the waveform diagram (FIG. 5) of the two-system PLL frequency synthesizer of the fourth embodiment are the same as those of the two-system PLL frequency synthesizer of the third embodiment, so description is omitted.

According to the two-system PLL frequency synthesizer of the fourth embodiment, the bias current I4 can be changed stepwise by turning on or off the switches 65a to 65d one by one sequentially. Therefore, rapid changes of the bias current I4 can be prevented, so it is possible to prevent fluctuations of the lock frequency of the second PLL frequency synthesizer 3b in a locking operation.

Note that although the two-system PLL frequency synthesizer of the fourth embodiment is configured to include four series-connected circuits 106 having the current mirror transistors (69a to 69d) and the switches (65a to 65d), the same effect can be achieved with a configuration having at least two series-connected circuits 106.

### FIFTH EMBODIMENT

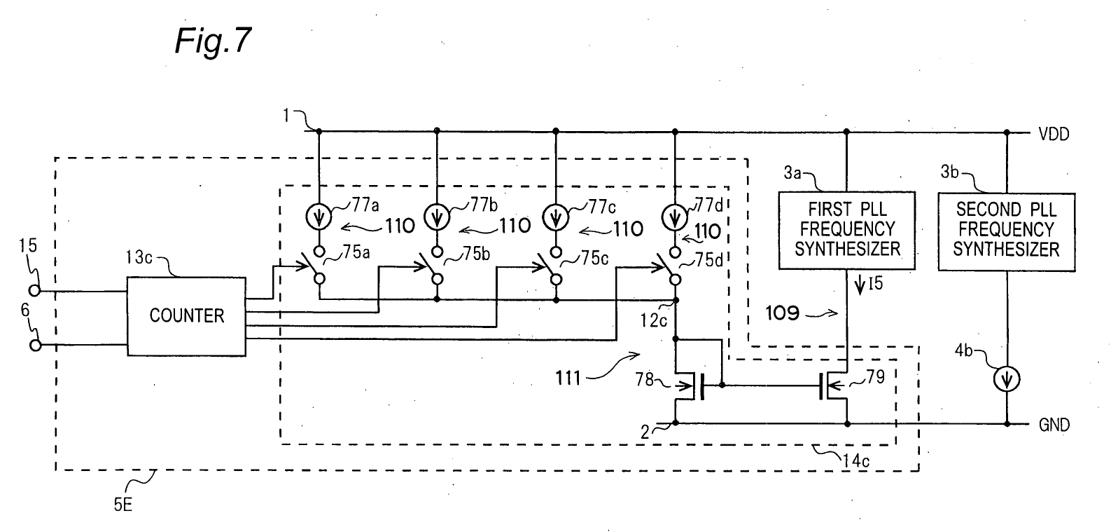

A two-system PLL frequency synthesizer according to a fifth embodiment of the present invention will be explained by using FIG. 7. The two-system PLL frequency synthesizer of the fifth embodiment is different from the two-system PLL frequency synthesizer of the third embodiment in such an aspect that a current amount controller 5E is provided instead of the current amount controller 5C. Other aspects are the same, so overlapping description is omitted.

FIG. 7 is a circuit diagram of the two-system PLL frequency synthesizer of the fifth embodiment. In FIG. 7, the current amount controller 5E includes: a current mirror circuit 14c having constant current sources 77a to 77d, current mirror transistors 78 and 79 and switches 75a to 75d; and a counter 13c.

Each of the constant current sources 77a to 77d generates an equal predetermined current. The constant current source 77a is connected in series with the switch 75a. Similarly, the constant current sources 77b to 77d are connected in series with the switches 75b to 75c, respectively. The switches 75a to 75d are one example of switching devices such as switching circuits using semiconductors. The respective series-connected circuits 110 having the respective constant current sources (77a to 77d) and the respective switches (75a to 75d ) are connected in parallel between the power line 1 and the current mirror transistor 78.

A series-connected circuit 109 of the current mirror transistor 79 and the first PLL frequency synthesizer 3a is connected in parallel with a series-connected circuit 111 of a parallel-connected circuit (75a to 75d and 77a to 77d ) having the respective series-connected circuits 110 and the current mirror transistor 78. The current mirror transistors 78 and 79 are MOSFETs. The gate of the current mirror transistor 78 is connected with the gate of the current mirror transistor 79 and a connecting point 12c of the switches 75a to 75d and the current mirror transistor 78.

The current value of the bias current I5 for operating the first PLL frequency synthesizer 3a becomes one that the sum of the current values of the respective constant current sources (77a to 77d) flowing via switches (75a to 75d) in the ON state is mirrored (copied) corresponding to the size ratio between the current mirror transistor 78 and the current mirror transistor 79.

The operation and the waveform diagram (Fig.5) of the two-system PLL frequency synthesizer of the fifth embodiment are the same as those of the two-system PLL frequency synthesizer of the third embodiment, so description is omitted.

According to the two-system PLL frequency synthesizer of the fifth embodiment, the bias current I4 can be changed stepwise by turning on or off the switches 75a to 75d one by one sequentially. Therefore, it is possible to prevent rapid changes of the bias current I4, and to prevent fluctuations of the lock frequency of the second PLL frequency synthesizer 3b in a locking operation.

Note that although the two-system PLL frequency synthesizer of the fifth embodiment is configured to include four series-connected circuits 110 having the switches (75a to 75d) and the constant current sources (77a to 77d), the same effect can be achieved with a configuration having at least two series-connected circuits 110.

Further, although the current values of the currents generated by the constant current sources 74a to 74d are equal respectively in the two-system PLL frequency synthesizer of the fifth embodiment, they may be weighted, respectively. That is, although the current values of the constant current sources 74a to 74d are set to (1:1:1:1), the same effect can be achieved by setting them to (1:2:4:8), for example.

Note that by combining any embodiments among the various embodiments described above appropriately, respective effects can be achieved.

The present invention is effectively used for a two-system PLL frequency synthesizer used for a wireless communication device such as a mobile telephone or a PHS.

Although the present invention is described sufficiently relating to preferred embodiments with reference to the accompanying drawings, various deformations and modifications thereof are obvious for those skilled in the technical. It should be understand that such deformations and modifications are included in the scope of the present invention defined by the scope of claims attached hereto unless they deviate therefrom.

The entire disclosure of Japanese Patent Application No. 2005-054667, filed on Feb. 28, 2005, including specification, drawings and claims is incorporated herein by reference in its entirety.

What is claimed is:

1. A two-system PLL frequency synthesizer comprising:
a first PLL frequency synthesizer connected with a power line;
a current amount controller including a first constant current source connected between the first PLL frequency synthesizer and a ground line, and a constant current source controller for controlling current of the first constant current source so as to change gradually; and
a series-connected circuit of a second PLL frequency synthesizer and a second constant current source, connected between the power line and the ground line.

2. The two-system PLL frequency synthesizer as claimed in claim 1, wherein the constant current source controller changes the current of the first constant current source continuously with respect to time.

3. The two-system PLL frequency synthesizer as claimed in claim 1, wherein the constant current source controller changes the current of the first constant current source stepwise.

4. The two-system PLL frequency synthesizer as claimed in claim 1, wherein the current amount controller includes, instead of the first constant current source and the constant current source controller:
a current mirror circuit connected in series with the first PLL frequency synthesizer;
a switching transistor, connected with the current mirror circuit, for controlling current of the current mirror circuit; and
a capacitor connected in parallel with the switching transistor.

5. The two-system PLL frequency synthesizer as claimed in claim 4, wherein the current mirror circuit includes:
a first current mirror transistor connected in series with the first PLL frequency synthesizer; and
a series-connected circuit of a third constant current source and a second current mirror transistor, connected in parallel with a series-connected circuit of the first PLL frequency synthesizer and the first current mirror transistor, and
a gate of the second current mirror transistor is connected with a gate of the first current mirror transistor, and a connecting point of the third constant current source and the second current mirror transistor.

6. The two-system PLL frequency synthesizer as claimed in claim 1, wherein the current amount controller includes, instead of the first constant current source and the constant current source controller:
a parallel-connected circuit, connected in series with the first PLL frequency synthesizer, in which a plurality of series-connected circuits of switching devices and constant current sources are connected in parallel; and
a counter for controlling on/off of the switching devices.

7. The two-system PLL frequency synthesizer as claimed in claim 1, wherein the current amount controller includes, instead of the first constant current source and the constant current source controller:
a parallel-connected circuit, connected in series with the first PLL frequency synthesizer, in which a plurality of series-connected circuits of switching devices and first current mirror transistors are connected in parallel;
a counter for controlling on/off of the switching devices;
a series-connected circuit of a third constant current source and a second current mirror transistor, connected in parallel with the first PLL frequency synthesizer and the series-connected circuits of the switching devices and the first current mirror transistors, and
a gate of the second current mirror transistor is connected with gates of the first current mirror transistors, and a connecting point of the third constant current source and the second current mirror transistor.

8. The two-system PLL frequency synthesizer as claimed in claim 1, wherein the current amount controller includes, instead of the first constant current source and the constant current source controller:
a first current mirror transistor connected in series with the first PLL frequency synthesizer;
a series-connected circuit of a parallel-connected circuit in which a plurality of series-connected circuits of constant current sources and switching devices are connected in parallel and a second current mirror transistor, connected in parallel with a series-connected circuit of the first PLL frequency synthesizer and the first current mirror transistor; and
a counter for controlling on/off of the switching devices, and
a gate of the second current mirror transistor is connected with a gate of the first current mirror transistor, and a connecting point of the switching devices and the second current mirror transistor.
